(19) United States
(12) Patent Application Publication
(10) Pub. No.: US 2018/0307141 A1
(43) Pub. Date: Oct. 25, 2018

(54) PHOTOSENSITIVE RESIN COMPOSITION AND CURED FILM PREPARED THEREFROM

(71) Applicant: Rohm and Haas Electronic Materials Korea Ltd., Cheonan (KR)

(72) Inventors: Jin Kwon, Hwaseong (KR); Geun Huh, Hwaseong (KR); Jong-Ho Na, Hwaseong (KR); Jong Han Yang, Hwaseong (KR)

(73) Assignee: Rohm and Haas Electronic Materials Korea Ltd., Cheonan (KR)

(21) Appl. No.: 15/769,944

(22) PCT Filed: Sep. 23, 2016
(86) PCT No.: PCT/KR2016/010639

§ 371 Date: Apr. 20, 2018

(30) Foreign Application Priority Data
Nov. 6, 2015 (KR) 10-2015-0155997
Sep. 23, 2016 (KR) 10-2016-0121881

(51) Int. Cl. G03F 7/075; G03F 7/023; G03F 7/038

(52) U.S. Cl. CPC G03F 7/0757; G03F 7/038; G03F 7/0233

(57) ABSTRACT

Disclosed herein are a photosensitive resin composition and a cured film prepared therefrom. The photosensitive resin composition includes a siloxane polymer, a 1,2-quinonediazide compound, an epoxy compound and at least one silane compound represented by formula 1. The silane compound together with the epoxy compound in the resin composition further reduces the number of highly reactive silanol group present in the siloxane polymer. As a result, the resistance (chemical resistance) to chemicals used in a post-processing can be maximized to provide a cured film having excellent stability.

### TECHNICAL FIELD

The present invention relates to a photosensitive resin composition and a cured film prepared therefrom. In particular, the present invention relates to a positive-type photosensitive resin composition, from which a cured film that has excellent chemical resistance is formed, and a cured film which prepared from the composition and used in a liquid crystal display (LCD) or an organic light-emitting diode (OLED).

### BACKGROUND ART

Generally, a transparent planarized film is formed on a thin film transistor (TFT) substrate for the purpose of insulation to prevent a contact between a transparent electrode and a data line in an LCD or an OLED. Through a transparent pixel electrode positioned near the data line, the aperture ratio of a panel may be increased and high brightness/resolution may be attained. In order to form such a transparent planarized film, several processing steps are employed to impart a specific pattern profile, and a positive-type photosensitive resin composition is widely employed in this process since fewer processing steps are required. Particularly, a positive-type photosensitive resin composition containing a siloxane polymer is well known as a material having high heat resistance, high transparency, and low dielectric constant.

A siloxane composition responsible for high heat resistance, high transparency and high resolution is known in the art. The conventional siloxane composition may be obtained by adding a 1,2-quinonediazide compound into a siloxane polymer in which a T-type siloxane structural unit having a phenyl residue and a Q-type siloxane structural unit are combined each other. For example, Korean Laid-open Patent Publication No. 2006-59202 discloses a composition including a siloxane polymer containing a phenolic hydroxyl group in an amount of 20 mole % or less, a quinonediazide compound (0.1 to 10 wt %) that contains no methyl group in the ortho- or para-position relative to the phenolic hydroxyl group therein, and a compound containing an alcoholic hydroxyl group and/or a cyclic compound containing a carbonyl group as a solvent. It also discloses a cured film prepared from the composition, which has at least 95% transmittance and satisfies a specific chromaticity coordinate.

Meanwhile, a planarized film prepared using a conventional positive-type photosensitive composition containing such siloxane composition or a display device employing same may have problems such as swelling or delamination of the film from a substrate when the cured film is immersed in, or comes into contact with, a solvent, an acid, a base, and the like which are used in a post-processing. Further, in line with the increasing demand on the high precision/resolution and in order to decrease a processing time, the concentration of a solvent, an acid, an alkali, and the like used in a post-processing becomes higher than before. Accordingly, the demand on a photosensitive resin composition, which may form a cured film having good chemical resistance, is increasing.

### DISCLOSURE OF INVENTION

### Technical Problem

Accordingly, it is an object of the present invention to provide a photosensitive resin composition which may form a cured film having good chemical resistance to chemicals (solvent, acid, alkali, and the like) used in a post-processing, and a cured film prepared therefrom used in an LCD, OLED and the like.

### Solution to Problem

In accordance with one aspect of the present invention, there is provided a photosensitive resin composition including (A) a siloxane polymer; (B) a 1,2-quinonediazide compound; (C) an epoxy compound; and (D) at least one silane compound represented by the following formula 1:

(R¹)ₙSi(OR²)₄₋ₙ [Formula 1]

In formula 1, R¹ is alkyl having 1 to 12 carbon atoms, alkenyl having 2 to 10 carbon atoms, or aryl having 6 to 15 carbon atoms, wherein, in case where a plurality of R¹ is present in the same molecule, each R¹ may be identical to or different from one another, and in case where R¹ is alkyl, alkenyl or aryl, hydrogen atoms may be partially or wholly substituted, and R¹ may include a structural unit containing a heteroatom;

R² is hydrogen, alkyl having 1 to 6 carbon atoms, acyl having 2 to 6 carbon atoms, or aryl having 6 to 15 carbon atoms, wherein, in case where a plurality of R² is present in the same molecule, each R² may be identical to or different from one another, and in case where R² is alkyl, acyl or aryl, hydrogen atoms may be partially or wholly substituted; and

n is an integer from 0 to 3.

### Advantageous Effects of Invention

Since the photosensitive resin composition includes an epoxy compound and a silane compound having a certain structure as well as a siloxane polymer, the number of highly reactive silanol groups present in the siloxane polymer may be further reduced. As a result, the resistance (chemical resistance) to chemicals used in a post-processing can be maximized to provide a cured film having excellent stability.

### BEST MODE FOR CARRYING OUT THE INVENTION

The photosensitive resin composition according to the present invention includes (A) a siloxane polymer, (B) a 1,2-quinonediazide compound, (C) an epoxy compound, and (D) at least one silane compound represented by formula 1, and may optionally further include (E) a solvent, (F) a surfactant, and/or (G) an adhesion assisting agent.

Hereinafter, each component of the photosensitive resin composition will be explained in detail.

In the present disclosure, “(meth)acryl” means “acryl” and/or “methacryl,” and “(meth)acrylate” means “acrylate” and/or “methacrylate.”

(A) Siloxane Polymer

The siloxane polymer (polysiloxane) includes a condensate of a silane compound and/or a hydrolysate thereof.

In this case, the silane compound or the hydrolysate thereof may be monofunctional to tetrafunctional silane compounds.

As a result, the siloxane polymer may include a siloxane structural unit selected from the following Q, T, D and M types.
Q type siloxane structural unit: a siloxane structural unit including a silicon atom and adjacent four oxygen atoms, which may be derived from e.g., a tetrafunctional silane compound or a hydrolysate of a silane compound having four hydrolysable groups.
T type siloxane structural unit: a siloxane structural unit including a silicon atom and adjacent three oxygen atoms, which may be derived from e.g., a trifunctional silane compound or a hydrolysate of a silane compound having three hydrolysable groups.
D type siloxane structural unit: a siloxane structural unit including a silicon atom and adjacent two oxygen atoms (i.e., linear siloxane structural unit), which may be derived from, e.g., a difunctional silane compound or a hydrolysate of a silane compound having two hydrolysable groups.
M type siloxane structural unit: a siloxane structural unit including a silicon atom and one adjacent oxygen atom, which may be derived from, e.g., a monofunctional silane compound or a hydrolysate of a silane compound having one hydrolysable group.

For example, the siloxane polymer (A) may include at least one structural unit derived from a silane compound represented by the following formula 2, and the siloxane polymer may be, for example, a condensate of a silane compound represented by the following formula 2 and/or a hydrolysate thereof.

(R³)ₙSi(OR⁴)₄₋ₙ [Formula 2]

In formula 2, R³ is alkyl having 1 to 12 carbon atoms, alkenyl having 2 to 10 carbon atoms, or aryl having 6 to 15 carbon atoms, wherein, in case where a plurality of R³ is present in the same molecule, each R³ may be identical to or different from one another, and in case where R³ is alkyl, alkenyl or aryl, hydrogen atoms may be partially or wholly substituted, and R³ may include a structural unit containing a heteroatom;

R⁴ is hydrogen, alkyl having 1 to 6 carbon atoms, acyl having 2 to 6 carbon atoms, or aryl having 6 to 15 carbon atoms, wherein, in case where a plurality of R⁴ is present in the same molecule, each R⁴ may be identical to or different from one another, and in case where R⁴ is alkyl, acyl or aryl, hydrogen atoms may be partially or wholly substituted; and

n is an integer from 0 to 3.

Examples of R³ including a structural unit containing a heteroatom may include ether, ester and sulfide.

The silane compound may be a tetrafunctional silane compound where n is 0, a trifunctional silane compound where n is 1, a difunctional silane compound where n is 2, and a monofunctional silane compound where n is 3.

Particular examples of the silane compound may include, e.g., as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane; as the trifuntional silane compound, methyltrichlorosilane, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d³-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compound, trimethylsilane, tributylsilane, trimethylmethoxysilane, tributylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, and butyltrimethoxysilane; preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

These silane compounds may be used alone or in combination of two or more thereof.

The conditions for preparing the hydrolysate of the silane compound represented by formula 2 or the condensate thereof are not specifically limited. For example, the desired hydrolysate or the condensate may be prepared by diluting the silane compound of formula 2 in a solvent such as ethanol, 2-propanol, acetone, and butyl acetate; adding thereto water necessary for the reaction, and, as a catalyst, an acid (e.g., hydrochloric acid, acetic acid, nitric acid, and the like) or a base (e.g., ammonia, triethylamine, cyclohexylamine, tetramethylammonium hydroxide, and the like); and then stirring the mixture thus obtained to complete the hydrolytic polymerization reaction.

The weight average molecular weight of the condensate (siloxane polymer) obtained by the hydrolytic polymerization of the silane compound of formula 2 is preferably in the range of 500 to 50,000. Within this range, the photosensitive resin composition may have desirable film-forming properties, solubility, and dissolution rates in a developer.

The kinds of the solvent and the acid or base catalyst used in the preparation and the amounts thereof may be optionally selected without specific limitation. The hydrolytic polymerization may be carried out at a low temperature of 20° C. or less, but the reaction may also be promoted by heating or refluxing. The time required for the reaction may vary depending on various conditions including the kind and concentration of the silane monomer, reaction temperature, etc. Generally, the reaction time required for obtaining a condensate having a weight average molecular weight of about 500 to 50,000 is in the range of 15 minutes to 30 days; however, the reaction time in the present invention is not limited thereto.

The siloxane polymer (A) may include a linear siloxane structural unit (i.e., D-type siloxane structural unit). The linear siloxane structural unit may be derived from a difunctional silane compound, for example, a silane compound represented by formula 2 where n is 2. Specifically, the siloxane polymer (A) includes the structural unit derived from the silane compound of formula 2 where n is 2 in a ratio of 0.5 to 50 mole %, and preferably 1 to 30 mole % based on an Si atomic mole number. Within this range, a cured film may maintain a constant hardness, and exhibit flexible properties, thereby further improving crack resistance with respect to external stress.

Further, the siloxane polymer (A) may include a structural unit derived from a silane compound represented by formula 2 where n is 1 (i.e., T-type structural unit). Preferably, the siloxane polymer (A) includes the structural unit derived from the silane compound represented by formula 2 where n is 1, in an amount of 40 to 85 mole %, more preferably 50 to 80 mole % based on an Si atomic mole number. Within this amount range, the photosensitive resin composition may form a cured film with a more precise pattern profile.

In addition, in consideration of the hardness, sensitivity, and retention rate of a cured film, it is preferable that the siloxane polymer (A) includes a structural unit derived from a silane compound having an aryl group. For example, the siloxane polymer (A) may include a structural unit derived from a silane compound having an aryl group in an amount of 30 to 70 mole %, and preferably 35 to 50 mole % based on an Si atomic mole number. Within this range, the compatibility of a siloxane polymer and a 1,2-naphthoquinonediazide compound is good, and thus, the excessive decrease in sensitivity may be prevented while attaining more favorable transparency of a cured film. The structural unit derived from the silane compound having an aryl group as R³ may be a structural unit derived from a silane compound of formula 2 where R³ is an aryl group, particularly a silane compound of formula 2 where n is 1 and R³ is an aryl group, more particularly a silane compound of formula 2 where n is 1 and R³ is phenyl (i.e., T-phenyl type structural unit).

The siloxane polymer (A) may include a structural unit derived from a silane compound represented by formula 2 where n is 0 (i.e., Q-type structural unit). Preferably, the siloxane polymer (A) includes the structural unit derived from the silane compound represented by formula 2 where n is 0, in an amount of 10 to 40 mole %, and preferably 15 to 35 mole % based on an Si atomic mole number. Within this range, the photosensitive resin composition may maintain its solubility in an aqueous alkaline solution at a proper degree during forming a pattern, thereby preventing any defects caused by a reduction in the solubility or a drastic increase in the solubility of the composition.

The term “mole % based on the Si atomic mole number” as used herein refers to the percentage of the number of moles of Si atoms contained in a certain structural unit with respect to the total number of moles of Si atoms contained in all of the structural units constituting the siloxane polymer.

The mole amount of the siloxane unit in the siloxane polymer (A) may be measured from the combination of Si-NMR, ¹H-NMR, ¹³C-NMR, IR, TOF-MS, elementary analysis, determination of ash, and the like. For example, in order to measure the mole amount of a siloxane unit having a phenyl group, an Si-NMR analysis is performed on a total siloxane polymer, a phenyl-bound Si peak area and a phenyl-unbound Si peak area are then analyzed, and the mole amount can thus be computed from the peak area ratio therebetween.

The photosensitive resin composition of the present invention may include the siloxane polymer (A) in an amount of 50 to 95 wt %, and preferably 65 to 90 wt % based on the total weight of the solid content of the composition excluding solvents. Within this amount range, the resin composition can maintain its developability at a suitable level, thereby producing a cured film with improved film retention rate and pattern resolution.

(B) 1,2-Quinonediazide Compound

The photosensitive resin composition according to the present invention includes a 1,2-quinonediazide compound (B).

The 1,2-quinonediazide compound may be any compound used as a photosensitive agent in the photoresist field.

Examples of the 1,2-quinonediazide compound include an ester of a phenolic compound and 1,2-benzoquinonediazide-4-sulfonic acid or 1,2-benzoquinonediazide-5-sulfonic acid; an ester of a phenolic compound and 1,2-naphthoquinonediazide-4-sulfonic acid or 1,2-naphthoquinonediazide-5-sulfonic acid; a sulfonamide of a phenolic compound in which a hydroxyl group is substituted with an amino group and 1,2-benzoquinonediazide-4-sulfonic acid or 1,2-benzoquinonediazide-5-sulfonic acid; a sulfonamide of a phenolic compound in which a hydroxyl group is substituted with an amino group and 1,2-naphthoquinonediazide-4-sulfonic acid or 1,2-naphthoquinonediazide-5-sulfonic acid. The above compounds may be used alone or in combination of two or more compounds, and the like.

Examples of the phenolic compound include 2,3,4-trihydroxybenzophenone, 2,4,6-trihydroxybenzophenone, 2,2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, 2,2,4-trimethyl-7,2′,4′-trihydroxyflavane, and the like.

More particular examples of the 1,2-quinonediazide compound include an ester of 2,3,4-trihydroxybenzophenone and 1,2-naphthoquinonediazide-4-sulfonic acid, an ester of 2,3,4-trihydroxybenzophenone and 1,2-naphthoquinonediazide-5-sulfonic acid, an ester of 4,4′-[1-[4-[1-[4-hydroxyphenyl]-1-methylethyl]phenyl]ethylidene]bisphenol and 1,2-naphthoquinonediazide-4-sulfonic acid, an ester of 4,4′-[1-[4-[1-[4-hydroxyphenyl]-1-methylethyl]phenyl]ethylidene]bisphenol and 1,2-naphthoquinonediazide-5-sulfonic acid, and the like.

The above compounds may be used alone or in combination of two or more compounds.

By using the aforementioned preferable compounds, the transparency of the positive-type photosensitive resin composition may be improved.

The 1,2-quinonediazide compound (B) may be included in the photosensitive resin composition in an amount ranging from 2 to 50 parts by weight, and preferably 5 to 20 parts by weight based on 100 parts by weight of the siloxane polymer (A) on the basis of the solid content excluding solvents. When the 1,2-quinonediazide compound is used in the above amount range, the resin composition may more readily form a pattern, while inhibiting the generation of defects such as a rough surface of a coated film and scum at the bottom portion of the pattern upon development.

(C) Epoxy Compound

In the photosensitive resin composition of the present invention, an epoxy compound is employed together with the siloxane polymer so as to increase the internal density of a siloxane binder, to thereby improve the chemical resistance of a cured film prepared therefrom.

The epoxy compound may be a homo oligomer or a hetero oligomer of an unsaturated monomer including at least one epoxy group.

Examples of the unsaturated monomer including at least one epoxy group may include glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, o-vinylbenzyl glycidyl ether, m-vinylbenzyl glycidyl ether, p-vinylbenzyl glycidyl ether, or a mixture thereof. Preferably, glycidyl methacrylate may be used.

The epoxy compound may be synthesized by any conventional methods known in the art.

An example of the commercially available epoxy compound may include GHP03 (glycidyl methacrylate homopolymer, Miwon Commercial Co., Ltd.).

The epoxy compound (C) may further include the following structural units.

Particular examples may include any structural unit derived from styrene; a styrene having an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; a styrene having a halogen such as fluorostyrene, chlorostyrene, bromostyrene, and iodostyrene; a styrene having an alkoxy substituent such as methoxystyrene, ethoxystyrene, and propoxystyrene; p-hydroxy-α-methylstyrene, acetylstyrene; an ethylenically unsaturated compound having an aromatic ring such as divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine having an N-vinyl group such as N-vinyl pyrrolidone, N-vinyl carbazole, and N-vinyl morpholine; an unsaturated ether such as vinyl methyl ether, and vinyl ethyl ether; an unsaturated imide such as N-phenylmaleimide, N-(4-chlorophenyl)maleimide, N-(4-hydroxyphenyl)maleimide, and N-cyclohexylmaleimide. The structural unit derived from the above exemplary compounds may be contained in the epoxy compound (C) alone or in combination of two or more thereof.

For polymerizability of the composition, styrene-based compounds are preferred among these examples.

Particularly, in terms of chemical resistance, it is more preferable that the epoxy compound (C) does not contain a carboxyl group, by not using a structural unit derived from a monomer containing a carboxyl group among these compounds.

The structural unit may be used in an amount ratio of 0 to 70 mole %, and preferably 10 to 60 mole % based on the total number of moles of the structural units constituting the epoxy compound (C). Within this amount range, a cured film may have desirable hardness.

The weight average molecular weight of the epoxy compound (C) may be in the range of 100 to 30,000, and preferably 1,000 to 15,000. If the weight average molecular weight of the epoxy compound is at least 100, a cured film may have improved hardness. Also, if the weight average molecular weight of the epoxy compound is 30,000 or less, a cured film may have a uniform thickness, which is suitable for planarizing any steps thereon. The weight average molecular weight is determined by gel permeation chromatography (GPC, eluent: tetrahydrofuran) using polystyrene standards.

In the photosensitive resin composition of the present invention, the epoxy compound (C) may be included in the photosensitive resin composition in an amount of 0.5 to 50 parts by weight, preferably 2 to 40 parts by weight, and more preferably 3 to 30 parts by weight based on 100 parts by weight of the siloxane polymer (A) on the basis of the solid content excluding solvents. Within the amount range, the sensitivity of the photosensitive resin composition may be improved.

(D) Silane Compound

The photosensitive resin composition of the present invention includes at least one silane compound represented by formula 1, particularly, a T-type and/or Q-type silane monomer together with an epoxy compound such as an epoxy oligomer, and the number of highly reactive silanol groups (Si—OH) in a siloxane polymer may be reduced, thereby improving chemical resistance during performing a post-processing:

(R¹)ₙSi(OR²)₄₋ₙ [Formula 1]

In formula 1, R¹ is alkyl having 1 to 12 carbon atoms, alkenyl having 2 to 10 carbon atoms, or aryl having 6 to 15 carbon atoms, wherein, in case where a plurality of R¹ is present in the same molecule, each R¹ may be identical to or different from one another, in case where R¹ is alkyl, alkenyl or aryl, hydrogen atoms may be partially or wholly substituted, and R¹ may include a structural unit having a heteroatom;

R² is hydrogen, alkyl having 1 to 6 carbon atoms, acyl having 2 to 6 carbon atoms, or aryl having 6 to 15 carbon atoms, wherein, in case where a plurality of R² is present in the same molecule, each R² may be identical to or different from one another, and in case where R² is alkyl, acyl or aryl, hydrogen atoms may be partially or wholly substituted; and

n is an integer from 0 to 3.

Examples of R¹ including a structural unit containing a heteroatom may include ether, ester and sulfide.

The silane compound may be a tetrafunctional silane compound where n is 0, a trifunctional silane compound where n is 1, a difunctional silane compound where n is 2, and a monofunctional silane compound where n is 3.

Particular examples of the silane compound may include, for example, as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane; as the trifuntional silane compound, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, phenyltrimethoxysilane, phenyltriethoxysilane, d³-methyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compound, trimethylsilane, tributylsilane, trimethylmethoxysilane, tributylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, butyltrimethoxysilane, 3-glycidoxypropyltrimethoxysilane, 3-glycidoxypropyltriethoxysilane, 2-(3,4-epoxycyclohexyl)ethyltrimethoxysilane, and 2-(3,4-epoxycyclohexyl)ethyltriethoxysilane; preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

These silane compounds may be used alone or in combination of two or more thereof.

The silane compound (D) may be included in an amount such that its solid content excluding solvents ranges from 0.5 to 18 parts by weight, 0.5 to 16 parts by weight, 0.5 to 12 parts by weight, 2 to 18 parts by weight, 2 to 16 parts by weight, 2 to 12 parts by weight, 2.3 to 18 parts by weight, 2.3 to 16 parts by weight, 2.3 to 12 parts by weight, 4 to 18 parts by weight, 4 to 16 parts by weight, or 4 to 12 parts by weight based on 100 parts by weight of the siloxane polymer (A). Within the range, the chemical resistance of the cured film thus manufactured may be further improved.

(E) Solvent

The photosensitive resin composition of the present invention may be prepared as a liquid composition in which the above components are mixed with a solvent. The solvent may be, for example, an organic solvent.

The amount of the solvent in the photosensitive resin composition according to the present invention is not specifically limited. For example, the photosensitive resin composition may contain the solvent in an amount such that its solid content ranges from 5 to 80 wt %, preferably 10 to 70 wt %, and more preferably 15 to 60 wt % based on the total weight of the photosensitive resin composition.

The solid content refers to all of the components included in the resin composition of the present invention excluding solvents. Within the amount range, coatability may be favorable, and an appropriate degree of flowability may be maintained.

The solvent of the present invention is not specifically limited as long as being capable of dissolving each component of the composition and being chemically stable. Examples of the solvent may include alcohol, ether, glycol ether, ethylene glycol alkyl ether acetate, diethylene glycol, propylene glycol monoalkyl ether, propylene glycol alkyl ether acetate, propylene glycol alkyl ether propionate, aromatic hydrocarbon, ketone, ester and the like.

Particular examples of the solvent include methanol, ethanol, tetrahydrofuran, dioxane, methyl cellosolve acetate, ethyl cellosolve acetate, ethyl acetoacetate, ethylene glycol monomethyl ether, ethylene glycol monoethyl ether, ethylene glycol dimethyl ether, ethylene glycol diethyl ether, propylene glycol dimethyl ether, propylene glycol diethyl ether, diethylene glycol monomethyl ether, diethylene glycol monoethyl ether, diethylene glycol dimethyl ether, diethylene glycol ethyl methyl ether, propylene glycol monomethyl ether, propylene glycol monoethyl ether, propylene glycol monopropyl ether, dipropylene glycol dimethyl ether, dipropylene glycol diethyl ether, propylene glycol methyl ether acetate, propylene glycol ethyl ether acetate, propylene glycol propyl ether acetate, dipropylene glycol methyl ether acetate, propylene glycol butyl ether acetate, toluene, xylene, methyl ethyl ketone, 4-hydroxy-4-methyl-2-pentanone, cyclopentanone, cyclohexanone, 2-heptanone, γ-butyrolactone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 2-methoxypropionate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, N-methylpyrrolidone, and the like.

Preferred among these exemplary solvents are ethylene glycol alkyl ether acetate, diethylene glycol, propylene glycol mono alkyl ether, propylene glycol alkyl ether acetate, and ketone. Particularly, diethylene glycol dimethyl ether, diethylene glycol ethyl methyl ether, dipropylene glycol dimethyl ether, dipropylene glycol diethyl ether, propylene glycol monomethyl ether, propylene glycol monoethyl ether, propylene glycol methyl ether acetate, methyl 2-methoxypropionate, γ-butyrolactone, and 4-hydroxy-4-methyl-2-pentanone are preferred.

The above compounds may be used alone or in combination of two or more thereof.

(F) Surfactant

The photosensitive resin composition of the present invention may further include a surfactant to enhance its coatability.

The kind of the surfactant is not limited, but preferred are fluorine-based surfactants, silicon-based surfactants, non-ionic surfactants and the like.

Specific examples of the surfactants may include fluorine- and silicon-based surfactants such as FZ-2122 manufactured by Dow Corning Toray Silicon Co., Ltd., BM-1000, and BM-1100 manufactured by BM CHEMIE Co., Ltd., Megapack F-142 D, Megapack F-172, Megapack F-173, and Megapack F-183 manufactured by Dai Nippon Ink Kagagu Kogyo Co., Ltd., Florad FC-135, Florad FC-170 C, Florad FC-430, and Florad FC-431 manufactured by Sumitomo 3M Ltd., Sufron S-112, Sufron S-113, Sufron S-131, Sufron S-141, Sufron S-145, Sufron S-382, Sufron SC-101, Sufron SC-102, Sufron SC-103, Sufron SC-104, Sufron SC-105, and Sufron SC-106 manufactured by Asahi Glass Co., Ltd., Eftop EF301, Eftop EF303, and Eftop EF352 manufactured by Shinakida Kasei Co., Ltd., SH-28 PA, SH-190, SH-193, SZ-6032, SF-8428, DC-57, and DC-190 manufactured by Toray Silicon Co., Ltd.; non-ionic surfactants such as polyoxyethylene alkyl ethers including polyoxyethylene lauryl ether, polyoxyethylene stearyl ether, polyoxyethylene oleyl ether, and the like, polyoxyethylene aryl ethers including polyoxyethylene octylphenyl ether, polyoxyethylene nonylphenyl ether, and the like, and polyoxyethylene dialkyl esters including polyoxyethylene dilaurate, polyoxyethylene distearate, and the like; and organosiloxane polymer KP341 (manufactured by Shin-Etsu Kagagu Kogyo Co., Ltd.), (meth)acrylate-based copolymer Polyflow No. 57 and 95 (Kyoeisha Yuji Chemical Co., Ltd.), and the like. They may be used alone or in combination of two or more thereof.

The surfactant (F) may be contained in the photosensitive resin composition in an amount of 0.001 to 5 parts by weight, and preferably 0.05 to 2 parts by weight based on 100 parts by weight of the siloxane polymer (A) on the basis of the solid content excluding solvents. Within the amount range, the coatability of the composition may be improved.

(G) Adhesion Assisting Agent

The photosensitive resin composition of the present invention may additionally include an adhesion assisting agent to improve the adhesiveness with substrate.

The adhesion assisting agent may include at least one reactive group selected from the group consisting of a carboxyl group, a (meth)acryloyl group, an isocyanate group, an amino group, a mercapto group, a vinyl group and an epoxy group.

The kind of the adhesion assisting agent is not specifically limited. Examples thereof may include at least one selected from the group consisting of trimethoxysilyl benzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, γ-glycidoxypropyltriethoxysilane, N-phenylaminopropyltrimethoxysilane, and β-(3,4-epoxycyclohexyl)ethyltrimethoxysilane, and preferable examples may include γ-glycidoxypropyltriethoxysilane, γ-glycidoxypropyltrimethoxysilane, or N-phenylaminopropyltrimethoxysilane, which may increase retention rate and have good adhesiveness with a substrate.

The adhesion assisting agent (G) may be contained in an amount of 0.001 to 5 parts by weight, preferably 0.01 to 2 parts by weight based on 100 parts by weight of the siloxane polymer (A) on the basis of the solid content excluding solvents. Within the amount range, the deterioration of resolution may be prevented, and the adhesiveness with a substrate may be further improved.

Besides, other additive components may be included in the photosensitive resin composition of the present invention only if the physical properties thereof are not adversely affected.

The photosensitive resin composition of the present invention may be used as a positive-type photosensitive resin composition.

Particularly, the photosensitive resin composition of the present invention is prepared by introducing T-type and/or Q-type silane monomers into a composition including a siloxane polymer, a 1,2-quinonediazide compound, and an epoxy compound, and the silane monomer together with the epoxy compound in the resin composition may efficiently reduce the number of the highly reactive silanol groups (Si—OH) present in the siloxane polymer. Accordingly, the cured film thus manufactured may have improved chemical resistance to chemicals (solvent, acid, alkali, and the like) used in a post-processing.

Further, the present invention provides a cured film prepared from the photosensitive resin composition.

The cured film may be prepared by a method known in the art, for instance, by coating the photosensitive resin composition on a substrate and subjecting it to a curing process.

The coating process may be carried out by means of a spin coating method, a slit coating method, a roll coating method, a screen printing method, an applicator method, and the like, in a desired thickness of, e.g., 2 to 25 μm.

For the curing of the photosensitive resin composition, for example, the composition coated on a substrate may be subjected to pre-bake at a temperature of, for example, 60 to 130° C. to remove solvents; then exposed to light using a photomask having a desired pattern; and subjected to development using a developer, for example, a tetramethylammonium hydroxide (TMAH) solution, to form a pattern on the coated film. The light exposure may be carried out at an exposure rate of 10 to 200 mJ/cm² based on a wavelength of 365 nm in a wavelength band of 200 to 500 nm. As a light source used for the exposure (irradiation), a low pressure mercury lamp, a high pressure mercury lamp, an extra high pressure mercury lamp, a metal halide lamp, an argon gas laser, etc., may be used; and X-ray, electronic ray, etc., may also be used, if desired.

Then, the coated film with a pattern is subjected to post-bake, if necessary, for instance, at a temperature of 150 to 300° C. for 10 minutes to 5 hours to prepare a desired cured film.

The cured film thus prepared has excellent physical properties in terms of heat resistance, transparency, dielectric constant, solvent resistance, acid resistance, and alkali resistance.

Therefore, the cured film has excellent light transmittance without surface roughness when the composition is subjected to heat treatment or is immersed in, or comes into contact with a solvent, an acid, a base, etc. Thus, the cured film can be used effectively as a planarized film for a TFT substrate of an LCD or an OLED; a partition of an OLED; an interlayer dielectric of a semiconductor device; a core or cladding material of an optical waveguide, etc.

Furthermore, the present invention provides electronic parts including the cured film as a protective film.

### MODE FOR THE INVENTION

Hereinafter, the present invention will be described in more detail with reference to the following examples. However, these examples are only provided to illustrate the present invention, and the scope of the present invention is not limited thereto.

In the following examples, the weight average molecular weight is determined by gel permeation chromatography (GPC) using a polystyrene standard.

### Synthetic Example 1: Synthesis of Siloxane Polymer (a)

To a reactor equipped with a reflux condenser, 40 wt % of phenyltrimethoxysilane, 15 wt % of methyltrimethoxysilane, 20 wt % of tetraethoxysilane, and 20 wt % of pure water were added, and then, 5 wt % of propylene glycol monomethyl ether acetate (PGMEA) was added thereto, followed by refluxing and stirring the mixture in the presence of 0.1 wt % of an oxalic acid catalyst for 7 hours, and then cooling. After that, the reaction product was diluted with PGMEA so that a solid content was 40 wt %. A siloxane polymer having a weight average molecular weight of about 5,000 to 8,000 Da was synthesized.

### Synthetic Example 2: Synthesis of Siloxane Polymer (b)

To a reactor equipped with a reflux condenser, 20 wt % of phenyltrimethoxysilane, 30 wt % of methyltrimethoxysilane, 20 wt % of tetraethoxysilane, and 15 wt % of pure water were added, and then, 15 wt % of PGMEA was added thereto, followed by refluxing and stirring the mixture in the presence of 0.1 wt % of an oxalic acid catalyst for 6 hours, and then cooling. After that, the reaction product was diluted with PGMEA so that a solid content was 30 wt %. A siloxane polymer having a weight average molecular weight of about 10,000 to 14,000 Da was synthesized.

### Synthetic Example 3: Synthesis of Siloxane Polymer (c)

To a reactor equipped with a reflux condenser, 20 wt % of phenyltrimethoxysilane, 30 wt % of methyltrimethoxysilane, 20 wt % of tetraethoxysilane, and 15 wt % of pure water were added, and then, 15 wt % of PGMEA was added thereto, followed by refluxing and stirring the mixture in the presence of 0.1 wt % of an oxalic acid catalyst for 5 hours, and then cooling. After that, the reaction product was diluted with PGMEA so that a solid content was 30 wt %. A siloxane polymer having a weight average molecular weight of about 10,000 to 15,000 Da was synthesized.

### Synthetic Example 4: Synthesis of Epoxy Compound

A three-necked flask equipped with a condenser was placed on a stirrer with an automatic temperature controller. 100 parts by weight of a monomer consisting of glycidyl methacrylate (100 mole %), 10 parts by weight of 2,2′-azobis(2-methylbutyronitrile), and 100 parts by weight of PGMEA were put in the flask, and the flask was charged with nitrogen. The flask was heated to 80° C. while stirring the mixture slowly, and the temperature was maintained for 5 hours to obtain an epoxy compound having a weight average molecular weight of about 6,000 to 10,000 Da. Then, PGMEA was added thereto to adjust the solid content thereof to 20 wt %.

### Examples and Comparative Examples: Preparation of Photosensitive Resin Compositions

Photosensitive resin compositions of the following examples and comparative examples were prepared using the compounds obtained in the above synthetic examples.

Besides, the following compounds were used in the examples and comparative examples:
1,2-quinonediazide compound: TPA-517, Miwon Commercial Co., Ltd.
   PAC-BIOC25, Miwon Commercial Co., Ltd.
solvent: PGMEA, Chemtronics Co., Ltd.
   gamma-butyrolactone (GBL), BASF
silane compound: phenyltrimethoxysilane (PhTMOS), Z-6124 silane, Xiameter®
   methyltrimethoxysilane (MTMOS), Z-6070 silane, Xiameter®
   tetraethoxysilane (TEOS), Dow Corning Co., Ltd.
   2-(3,4-epoxycyclohexyl)ethyltrimethoxysilane (ECHTMOS), Sigma-Aldrich Co.
   3-glycidoxypropyltrimethoxysilane (GPTMS), Z-6040 silane, Xiameter®
surfactant: silicon leveling surfactant, FZ-2122, Dow Corning Toray Co., Ltd.

### Example 1

27.3 parts by weight of a solution of the siloxane polymer (a) of Synthetic Example 1, 36.5 parts by weight of a solution of the siloxane polymer (b) of Synthetic Example 2, and 36.2 parts by weight of a solution of the siloxane polymer (c) of Synthetic Example 3 were mixed, and then, 5.6 parts by weight of TPA-517 and 0.2 pars by weight of PAC-BIOC25 as 1,2-quinonediazide compounds, 23.7 parts by weight of the epoxy compound of Synthetic Example 4, and 2.3 parts by weight of PhTMOS as a silane monomer, and 1.1 parts by weight of a surfactant based on 100 parts by weight of the total siloxane polymers were uniformly mixed. The mixture was dissolved in a mixture of PGMEA and GBL (PGMEA:GBL=85:15 by weight) as a solvent so that a solid content was 22%. The mixture was filtered using a membrane filter having 0.2 μm pores to obtain a composition having a solid content of 22 wt %.

### Example 2

A composition having a solid content of 22 wt % was obtained by conducting the same procedure described in Example 1 except for using 6.0 parts by weight of TPA-517 and 0.2 part by weight of PAC-BIOC25 as the 1,2-quinonediazide compounds, 5 part by weight of PhTMOS as the silane monomer, 1.2 part by weight of the surfactant, and the solvent in a weight ratio of PGMEA:GBL=86:14.

### Example 3

A composition having a solid content of 22 wt % was obtained by conducting the same procedure described in Example 1 except for using 2.3 parts by weight of MTMOS as the silane monomer.

### Example 4

A composition having a solid content of 22 wt % was obtained by conducting the same procedure described in Example 3 except for using 6.0 parts by weight of TPA-517 and 0.2 part by weight of PAC-BIOC25 as the 1,2-quinonediazide compounds, 5 parts by weight of MTMOS as the silane monomer, 1.2 parts by weight of the surfactant, and the solvent in a weight ratio of PGMEA:GBL=86:14.

### Example 5

A composition having a solid content of 22 wt % was obtained by conducting the same procedure described in Example 1 except for using 2.3 parts by weight of TEOS as the silane monomer.

### Example 6

A composition having a solid content of 22 wt % was obtained by conducting the same procedure described in Example 5 except for using 6.0 parts by weight of TPA-517 and 0.2 part by weight of PAC-BIOC25 as the 1,2-quinonediazide compounds, 5 parts by weight of TEOS as the silane monomer, 1.2 parts by weight of the surfactant, and the solvent in a weight ratio of PGMEA:GBL=86:14.

### Example 7

A composition having a solid content of 22 wt % was obtained by conducting the same procedure described in Example 6 except for using 5 parts by weight of ECHTMOS as the silane monomer.

### Example 8

A composition having a solid content of 22 wt % was obtained by conducting the same procedure described in Example 7 except for using 5 parts by weight of GPTMS as the silane monomer.

### Comparative Example 1

A composition having a solid content of 22 wt % was obtained by conducting the same procedure described in Example 1 except for using 5.3 parts by weight of TPA-517 and 0.2 part by weight of PAC-BIOC25 as the 1,2-quinonediazide compounds, and the solvent in a weight ratio of PGMEA:GBL=86:14, and not using the silane monomer.

### Comparative Example 2

100 parts by weight of a solution of the siloxane polymer (a) of Synthetic Example 1, and 6.2 parts by weight of TPA-517 and 0.2 part by weight of PAC-BIOC25 as the 1,2-quinonediazide compounds, 4.5 parts by weight of PhTMOS as the silane monomer, and 1.2 parts by weight of the surfactant based on 100 parts by weight of the siloxane polymer (a) were uniformly mixed. The mixture was dissolved in a mixture of PGMEA and GBL (PGMEA:GBL=90:10 by weight) as the solvent so that the solid content was 22%. The mixture was filtered using a membrane filter having 0.2 μm pores to obtain a composition having a solid content of 22 wt %.

### Comparative Example 3

A composition having a solid content of 22 wt % was obtained by conducting the same procedure described in Comparative Example 2 except for using 4.5 parts by weight of ECHTMOS as the silane monomer.

### Comparative Example 4

A composition having a solid content of 22 wt % was obtained by conducting the same procedure described in Comparative Example 2 except for using 4.5 parts by weight of GPTMS as the silane monomer.

### Experimental Example 1: Evaluation of Chemical Resistance

Each of the compositions obtained in the examples and comparative examples was coated onto a glass substrate by spin coating and pre-baked on a hot plate kept at 110° C. for 90 seconds to form a dried film having a thickness of 3.1 μm. The dried film was developed with an aqueous solution of 2.38 wt % tetramethylammonium hydroxide through stream nozzles at 23° C. for 60 seconds. Then, the developed film was exposed to light through a pattern mask at an exposure rate of 200 mJ/cm² based on a wavelength of 365 nm for a certain period using an aligner (model name: MA6), which emits light having a wavelength of 200 nm to 450 nm (bleaching process). The exposed film was then heated in a convection oven at 230° C. for 30 minutes to obtain a cured film. The thickness (T1) of the cured film was measured using a non-contact type thickness measuring device (SNU Precision).

A rework chemical (product name: LT-360) was introduced to a constant temperature bath and then the temperature was maintained at 50° C. The cured film was immersed in the bath for 10 minutes, and the rework chemical was removed by air. Then, the thickness (T2) of the cured film was measured.

The chemical resistance was evaluated from the measured values via the following equation 1 (swelling thickness was calculated after the evaluation experiment of the chemical resistance).

[Equation 1]

Swelling thickness after evaluation experiment on chemical resistance (A)=film thickness after immersing into rework chemical (T2)−film thickness before immersing into rework chemical (T1)

### Experimental Example 2: Evaluation of Sensitivity

Each of the compositions obtained in the examples and comparative examples was coated onto a silicon nitride substrate by spin coating, and the coated substrate was pre-baked on a hot plate kept at 110° C. for 90 seconds to form a dried film. The dried film was exposed to light, through a mask having a pattern consisting of square holes in sizes ranging from 2 m to 25 m, at an exposure rate of 0 to 200 mJ/cm² based on a wavelength of 365 nm for a certain time period using an aligner (model name: MA6), which emits light having a wavelength of 200 nm to 450 nm, and was developed by spraying an aqueous developer of 2.38 wt % tetramethylammonium hydroxide through spray nozzles at 23° C. The exposed film was then heated in a convection oven at 230° C. for 30 minutes to obtain a cured film having a thickness of 3.0 km.

For the hole pattern formed through a mask having a size of 10 μm, the amount of exposure energy required for attaining a critical dimension (CD, line width, km) of 10 jam was measured. The lower the exposure energy is, the better the sensitivity of a cured film is.

### Experimental Example 3: Evaluation of Resolution

In order to measure the resolution of the cured film pattern manufactured from the photosensitive resin compositions obtained by the examples and the comparative examples, the minimum size of the pattern was observed using a micro optical microscope (STM6-LM manufactured by Olympus), and the resolution was measured. That is, the minimum pattern dimension after curing with optimal light exposure rate, when the critical dimension (CD: line width, unit: km) of the patterned hole pattern with 10 m was 10 μm, was measured. The lower the resolution value is, the better the resolution is.

### Experimental Example 4: Evaluation of Film Retention Rate

The same procedures as in Experimental Example 3 including pre-baking, light exposure to light through a mask, development, and thermal curing were repeated for each of the compositions obtained in the examples and comparative examples to prepare a cured film. The film retention rate was obtained by calculating the percentage of the thickness of the final cured film relative to the thickness of the cured film right after the pre-baking process using a non-contact type thickness measuring device (SNU Precision).

Experimental results are summarized in the following Table 1.

TABLE 1

| | Chemical | Sensitivity | Resolution | Retention rate |
|---|---|---|---|---|
| | resistance (Å) | (mJ/cm²) | (μm) | (%) |
| Example 1 | 483 | 45 | 3-4 | 96 |
| Example 2 | 1620 | 50 | 4 | 93 |
| Example 3 | 1317 | 55 | 4-5 | 93 |
| Example 4 | 1344 | 55 | 3-4 | 97 |
| Example 5 | 1306 | 50 | 3-4 | 96 |
| Example 6 | 1839 | 55 | 3-4 | 94 |
| Example 7 | 1113 | 32.5 | 6 | 88 |
| Example 8 | 1723 | 35 | 6 | 90 |
| Comparative | 2359 | 65 | 4 | 97 |
| Example 1 | | | | |
| Comparative | 2987 | 40 | 6-7 | 80 |
| Example 2 | | | | |
| Comparative | 2977 | 65 | 10 | 67 |
| Example 3 | | | | |
| Comparative | 3394 | 28 | 7 | 66 |
| Example 4 | | | | |

As shown in Table 1, the cured films formed from the compositions of the present invention exhibited good chemical resistance, sensitivity, developability, and retention rate. In contrast, the compositions according to the comparative examples, which are not included in the scope of the present invention, exhibited at least one inferior result.

What is claimed is:

1. A photosensitive resin composition, comprising:
(A) a siloxane polymer;
(B) a 1,2-quinonediazide compound;
(C) an epoxy compound; and
(D) at least one silane compound represented by the following formula 1:
(R¹)ₙSi(OR²)₄₋ₙ [Formula 1]
in formula 1, R¹ is alkyl having 1 to 12 carbon atoms, alkenyl having 2 to 10 carbon atoms, or aryl having 6 to 15 carbon atoms, wherein, in case where a plurality of R¹ is present in the same molecule, each R¹ may be identical to or different from one another, and in case where R¹ is alkyl, alkenyl or aryl, hydrogen atoms may be partially or wholly substituted, and R¹ may include a structural unit containing a heteroatom;
R² is hydrogen, alkyl having 1 to 6 carbon atoms, acyl having 2 to 6 carbon atoms, or aryl having 6 to 15 carbon atoms, wherein, in case where a plurality of R² is present in the same molecule, each R² may be identical to or different from one another, and in case where R² is alkyl, acyl or aryl, hydrogen atoms may be partially or wholly substituted; and
n is an integer from 0 to 3.

2. The photosensitive resin composition of claim 1, wherein the epoxy compound (C) dose not include a carboxyl group.

3. The photosensitive resin composition of claim 1, wherein the siloxane polymer (A) comprises at least one structural unit derived from a silane compound represented by the following formula 2:
(R³)ₙSi(OR⁴)₄₋ₙ [Formula 2]
in formula 2, R³ is alkyl having 1 to 12 carbon atoms, alkenyl having 2 to 10 carbon atoms, or aryl having 6 to 15 carbon atoms, wherein, in case where a plurality of R³ is present in the same molecule, each R³ may be identical to or different from one another, and in case where R³ is alkyl, alkenyl or aryl, hydrogen atoms may be partially or wholly substituted, and R³ may comprise a structural unit containing a heteroatom;
R⁴ is hydrogen, alkyl having 1 to 6 carbon atoms, acyl having 2 to 6 carbon atoms, or aryl having 6 to 15 carbon atoms, wherein, in case where a plurality of R⁴ is present in the same molecule, each R⁴ may be identical to or different from one another, and in case where R⁴ is alkyl, acyl or aryl, hydrogen atoms may be partially or wholly substituted; and
n is an integer from 0 to 3.

4. The photosensitive resin composition of claim 3, wherein the siloxane polymer (A) comprises a structural unit derived from a silane compound of formula 2 where n is 0.

5. The photosensitive resin composition of claim 1, wherein the at least one silane compound (D) is comprised in an amount of 0.5 to 18 parts by weight based on 100 parts by weight of the solid content of the siloxane polymer.
